(19) United States
(12) Patent Application Publication
(10) Pub. No.: US 2012/0040519 A1
(43) Pub. Date: Feb. 16, 2012

(54) METHOD FOR FORMING SILICON FILM HAVING MICROCRYSTAL STRUCTURE

(75) Inventor: Ching-Ting LEE, Taoyuan County (TW)

(73) Assignee: BUREAU OF ENERGY, MINISTRY OF ECONOMIC AFFAIRS, Taipei City (TW)

(21) Appl. No.: 13/117,722

(22) Filed: May 27, 2011

(30) Foreign Application Priority Data
Aug. 13, 2010 (TW) 99127170

(51) Int. Cl. H01L 21/205

(52) U.S. Cl. 438/488; 257/E21.102

(57) ABSTRACT

A method for forming a silicon film having a microcrystal structure is provided. The method includes following steps. A plasma-enhanced chemical vapor deposition system having a reaction chamber, a top electrode and a bottom electrode is provided. The top electrode and the bottom electrode are opposite and disposed in the reaction chamber. A substrate is disposed on the bottom electrode. A silane gas is applied into the reaction chamber. A silicon film having a microcrystal structure is formed by simultaneously irradiating the silane gas in the reaction chamber by a carbon dioxide laser and performing a plasma-enhanced chemical vapor deposition step.

This application claims the benefit of Taiwan application Serial No. 99127170, filed Aug. 13, 2010, the subject matter of which is incorporated herein by reference.

### BACKGROUND

1. Technical Field

The disclosure relates in general to a method for forming a silicon film, and more particularly to a method for forming a silicon film having a microcrystal structure.

2. Description of the Related Art

A silicon material can be adjusted to have n-type conductivity or p-type conductivity by a proper doing treatment. A p-n junction is constructed by the n-type silicon and the p-type silicon in a silicon solar cell. As the solar cell is irradiated by sunlight, an electron-hole pair is generated by absorbing the photon by the junction depletion region. The accumulating positive and negative charges are absorbed by an electrode. After the electrode is connected with a load, an electrical current is generated due to a potential difference. Therefore, the light energy is transformed into the electrical energy by the solar cell.

The single crystal silicon is mainly used in the silicon solar cell early. However, it is not easy to get the single crystal silicon and the single crystal silicon is expensive. The trend of the material is directed toward other substitutive materials, such as a recovered silicon material or other non-single crystal materials.

However, a solar cell using an amorphous silicon film has a photoelectric conversion lower than that of a solar cell using a single crystal silicon or polycrystal silicon having an atomic arrangement order in a long or short range better than that of the amorphous silicon film. In addition, the stability of the amorphous silicon film solar cell is limited due to Staebler-Wronski effect, that is, a long-term irradiation results in degradation of the film quality and photoconductivity.

In 1974, it is found that the conductivity of the amorphous silicon can be stabilized and the probability of the light-induced degradation can be decreased by filling a hydrogen atom into a dangling bond of the amorphous silicon for decreasing the recombination center of the deep level and the recombination probability of the carrier.

Currently in some researches, the silicon material is transformed into the crystal phase from the amorphous phase by certain methods. For example, it is found the silicon material can be changed into the microcrystal phase from the microcrystal structure phase by adjusting the hydrogen flow rate. However, the hydrogen atom in the silicon material must be moderate for preventing from a loose structure.

Z. Tang et al. (Z. Tang, W. Wang, B. Zhou, D. Wang, S. Peng, and D. He, “The influence of H₂/(H₂+Ar) ratio on microstructure and optoelectronic properties of microcrystalline silicon films deposited by plasma-enhanced CVD”, Appl. Surf. Sci., 255, 8867 (2009) use a plasma-enhanced chemical vapor deposition system to deposit the amorphous silicon film by parameters of a SiH₄ flow rate: H₂ flow rate of 30:100, a pressure of a reaction chamber of 800 mtorr, and a temperature of a substrate of 400° C. Next, the formed amorphous silicon film is transformed into a microcrystal structure by a high temperature of 550° C.-850° C. However, the high temperature process is not suitable for the glass or polymer substrate not temperature resistant material. The method for forming this kind of the silicon film having the microcrystal structure could only applied a limited condition.

### SUMMARY

A method for forming a silicon film is provided. The method comprises following steps. A substrate is disposed in an environment having a silicon containing alkane gas. A silicon film is formed on the substrate by simultaneously irradiating the silicon containing alkane gas by a carbon dioxide laser and performing a plasma-enhanced chemical vapor deposition step.

A method for forming a silicon film having a microcrystal structure is provided. The method comprises following steps. A plasma-enhanced chemical vapor deposition system is provided. The plasma-enhanced chemical vapor deposition system comprises a reaction chamber, a top electrode and a bottom electrode. The top electrode and the bottom electrode opposite to the top electrode are disposed in the reaction chamber. The substrate is disposed on the bottom electrode. A silane gas is supplied into the reaction chamber. A silicon film having a microcrystal structure is formed by simultaneously irradiating the silane gas by a carbon dioxide laser in the reaction chamber and performing a plasma-enhanced chemical vapor deposition step.

### BRIEF DESCRIPTION OF THE DRAWINGS

FIG. 1 and FIG. 2 show a reaction device in one embodiment.

FIG. 3A, FIG. 3B, FIG. 3C, FIG. 3D and FIG. 3E respectively shows Raman spectral curves of the silicon films formed by using the laser power of 0 W, 23 W, 45 W, 68 W and 90 W.

FIG. 4A, FIG. 4B, FIG. 4C, FIG. 4D and FIG. 4E respectively show analysis results of the silicon film, formed by using the laser power of 0 W, 23 W, 45 W, 68 W and 90 W, measured by the Fourier transform infrared spectrophotometer.

### DETAILED DESCRIPTION

In Embodiments of the application, a silicon film having a microcrystal structure can be formed under a low temperature due to using a plasma-enhanced chemical vapor deposition in combination with using a carbon dioxide laser. The low temperature process used in embodiments allows using various substrates not temperature resistant such as glass or polymer, etc.

In embodiments of the application, a method for forming the silicon film having the microcrystal structure comprises following steps. A substrate is disposed in an environment containing a silicon-containing alkane gas. Next, the silicon film is formed on the substrate by simultaneously irradiating the silicon containing alkane gas by a carbon dioxide laser and performing a plasma-enhanced chemical vapor deposition.

In embodiments of the application, the silicon containing alkane gas comprises silane. The laser is carbon dioxide laser. For example, a power of the laser is 10 W-1000 W.

In one embodiment, for example, a temperature of the plasma-enhanced chemical vapor deposition is 25° C.-400° C. A power of the plasma-enhanced chemical vapor deposition is 10 W-1000 W. A pressure of the plasma-enhanced chemical vapor deposition is 0.1 torr-100 torr. A flow rate of the silicon containing alkane gas is 1 sccm-1500 sccm.

The silane gas has a high absorbing efficiency for a carbon dioxide laser having a wavelength of about 10.6 μm, and thus a dissociation rate of a Si—H bond of the silicon containing alkane gas is increased due to the carbon dioxide laser. Therefore, in one embodiment, by using the plasma-enhanced chemical vapor deposition system in combination with the carbon dioxide laser, the silicon film having the microcrystal structure can be formed by using a plasma power of a low frequency such as 13.56 MHz in an environment at a low temperature (25° C.-400° C.).

The advantages of the present disclosure are illustrated with the following examples of the present disclosure and comparative examples.

<Reaction Device>

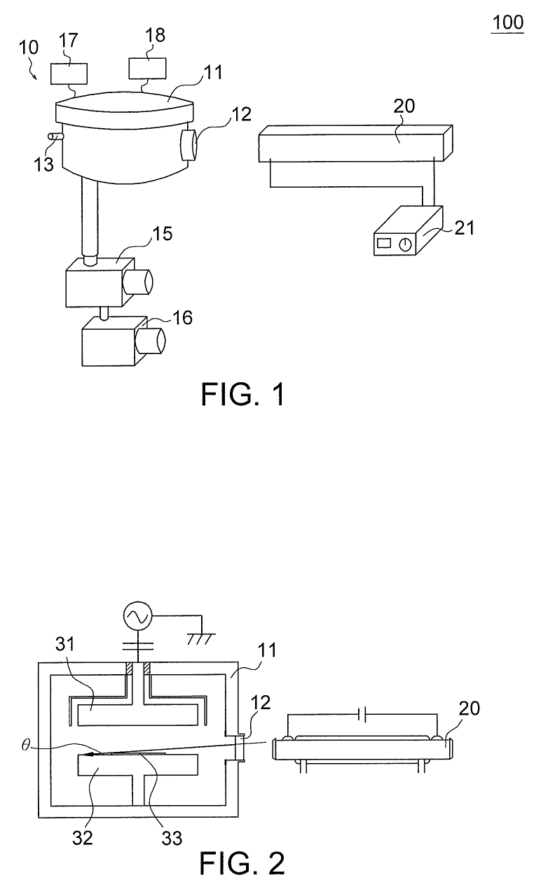

FIG. 1 and FIG. 2 illustrate a reaction device in embodiments. The reaction device comprises a plasma-enhanced chemical vapor deposition system 10 and a carbon dioxide laser system 20.

The plasma-enhanced chemical vapor deposition system 10 comprises following parts.

(1) A reaction chamber 11 has a diameter of about 40 cm. The reaction chamber 11 has a transparent window 12 which may be formed by glass, quartz or a transparent crystal chip, etc. A top electrode 31 (FIG. 2) and a bottom electrode 32 (FIG. 2) are disposed in the reaction chamber 11. Diameters of the top electrode 31 and the bottom electrode 32 are about 25 cm. The top electrode 31 is opposite to the bottom electrode 32. A gap between the top electrode 31 and the bottom electrode 32 is about 3 cm.

(2) A radio frequency of a radio frequency generator 17 is 13.65 MHz. A power of the radio frequency generator 17 matched with a LC can be up to 300 W. In addition, an output power value and a reflection power value can be read from a panel of the radio frequency generator 17 directly.

(3) A rotary pump 16 and a Roots pump 15 connected in series are used in a vacuum system. The rotary pump 16 has an automatic pressure controller for accurately controlling a pressure. The Roots pump 15 can generate a huge amount of an air displacement, increasing a rate of pumping the reaction chamber 11 to a vacuum state. A filter screen is disposed at a suction port of the pump for preventing the pump from defect due to a solid impurity.

(4) A master flow controller (MFC) 18 is used for accurately controlling a flow rate of a silicon containing alkane gas flowing into the reaction chamber 11 from a pipe 13. The pipe 13 also can be communicated with high-purity nitrogen for purging the pipe 13 after the reaction.

A laser wavelength of the carbon dioxide laser system 20 is 10.6 μm. A laser power of the carbon dioxide laser system 20 can be up to 100 W by using a laser controller 21. A path of the carbon dioxide laser system 20 is adjustable.

<Silicon Film Deposition>

In a process for depositing the silicon film, the substrate 33 is disposed on the bottom electrode 32 in the reaction chamber 11. Then, simultaneously, a plasma-enhanced chemical vapor deposition step is performed, and the silane (SiH₄) gas in the reaction chamber 11 is irradiated by the carbon dioxide laser through the transparent window 33 from the carbon dioxide laser system 20.

In the plasma-enhanced chemical vapor deposition step, the silane gas flowing into the reaction chamber 11 has a concentration of 4% and a flow rate of 250 sccm. An argon gas is used as a solvent for the silane gas. The pressure in the reaction chamber 11 is controlled to be 0.5 torr. The radio frequency is 13.65 MHz. The power is 300 W. The plasma-enhanced chemical vapor deposition step is performed in an environment having a room temperature (about 25° C.) for about 30 minutes.

The path of the laser from the carbon dioxide laser system 20 is controlled to cross above the substrate 33 and be as close to the substrate 33 as possible, for maximizing the reactive gas close to a surface of the substrate 33 to be irradiated by the laser and deposited onto the substrate 33. In this embodiment, the laser is stopped on the bottom electrode 32 at a left side of the substrate 33. An included angle θ between the laser and the bottom electrode 32 is about 2 degrees.

Results of the silicon film fromed by various carbon dioxide laser powers (of 0 W, 23 W, 45 W, 68 W and 90 W) are described below.

<Raman Spectrometry Test>

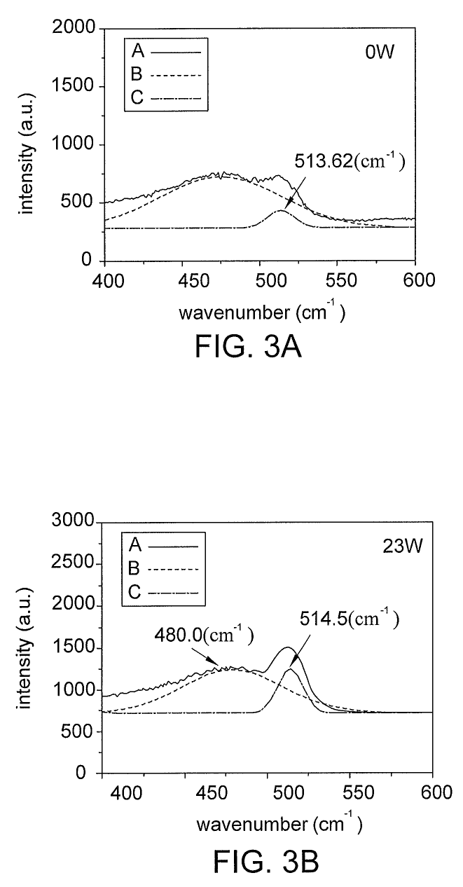

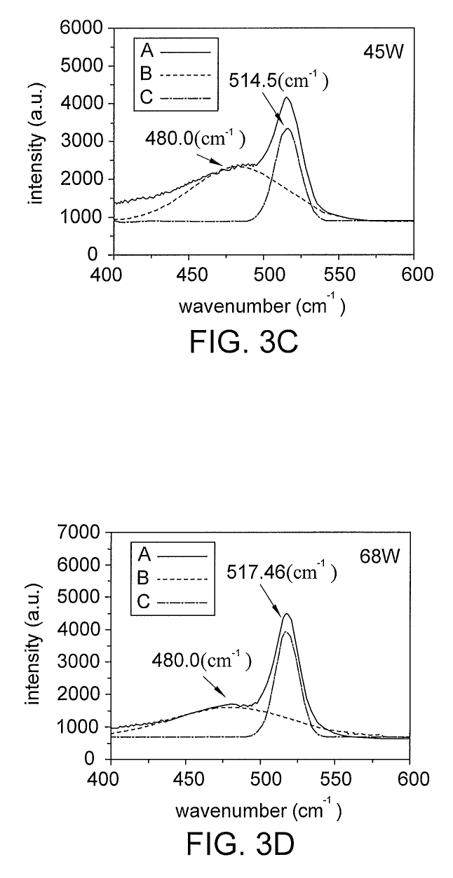

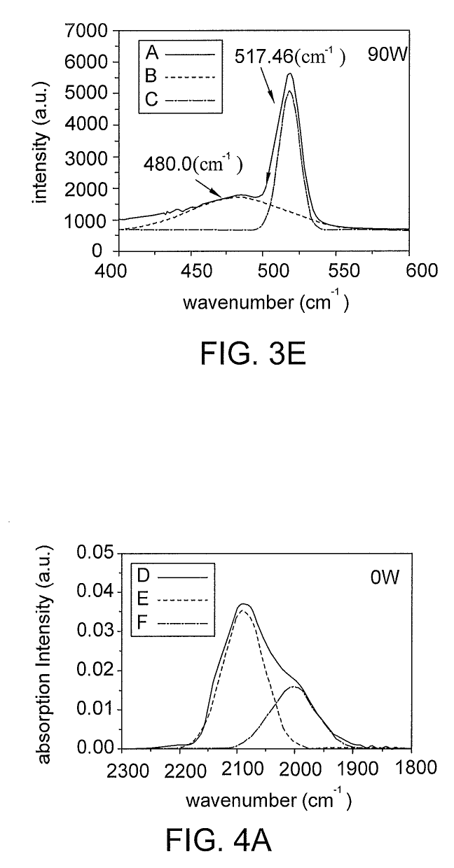

FIG. 3A, FIG. 3B, FIG. 3C, FIG. 3D and FIG. 3E respectively are Raman spectral figures of the silicon films formed by carbon dioxide laser powers of 0 W, 23 W, 45 W, 68 W and 90 W. The curve A is a result measured by a Raman spectrometer. The curve B and the curve C are fitted curves from the cuve A. The curve B and the curve C respectively have mode peaks at different positions of wavenumber.

Generally, in a result of the Raman spectrometer, an amorphous silicon would have a wide mode peak at about 480 cm⁻¹. A crystal silicon would have a narrow mode peak at about 520 cm⁻¹. As a crystallization degree of the crystal silicon becomes more high, a full width at half maximum (FWHM) of the mode peak is more narrow. Therefore, the single crystal silicon has the narrowest FWHM. The FWHM of the mode peak at 480 cm⁻¹ is bigger than the FWHM of the mode peak at 520 cm⁻¹. Thus, for example, as the structure of the film gradually becomes the crystal phase from the amorphous phase, the position of the mode peak would gradually shift to 520 cm^{-1 from} 480 cm⁻¹, and the FWHM would be narrower. In addition, as a ratio of the amorphous structure to the crystal structure of the film becomes smaller, a ratio of the area of the mode peak at 480 cm⁻¹ to the area of the mode peak at 520 cm⁻¹ would become smaller. Therefore, a relative relation between the crystal silicon and the amorphous silicon of the silicon film can be analyzed by the position, the FWHM and the area of the mode peak of the Raman spectral curve.

In FIG. 3A, FIG. 3B, FIG. 3C, FIG. 3D and FIG. 3E, the position of the mode peak of the curve B is at about 480.0 cm⁻¹, indicating the existence of the amorphous silicon. The position of the mode peak of the curve C is at about 513.6 cm⁻¹-518.4 cm⁻¹, indicating the existence of the crystal silicon. Table shows results obtained from FIG. 3A, FIG. 3B, FIG. 3C, FIG. 3D and FIG. 3E. The volume fraction X_{c} of the crystal structure is obtained by dividing the area of the mode peak of the curve C by a total area of the mode peak of the curve B and the mode peak of the curve C. From the result of table 1, it is found that as the power of the carbon dioxide laser becomes higher, a ratio of the crystal silicon structure to the amorphous silicon structure of the silicon film becomes higher.

TABLE 1

| | | volume fraction | |
|---|---|---|---|
| | Position of mode | of crystal | FWHM of |
| carbon dioxide | peak of curve A | structure | mode peak |
| laser power (W) | (cm⁻¹) | (X_{c}; %) | (cm⁻¹) |
| 0 | 513.6 | 13.2 | 19.0 |
| 23 | 514.5 | 20.1 | 17.9 |
| 45 | 515.5 | 29.1 | 16.8 |
| 68 | 517.4 | 37.3 | 15.1 |
| 90 | 518.4 | 46.6 | 14.3 |

<Infrared Spectrometry Test>

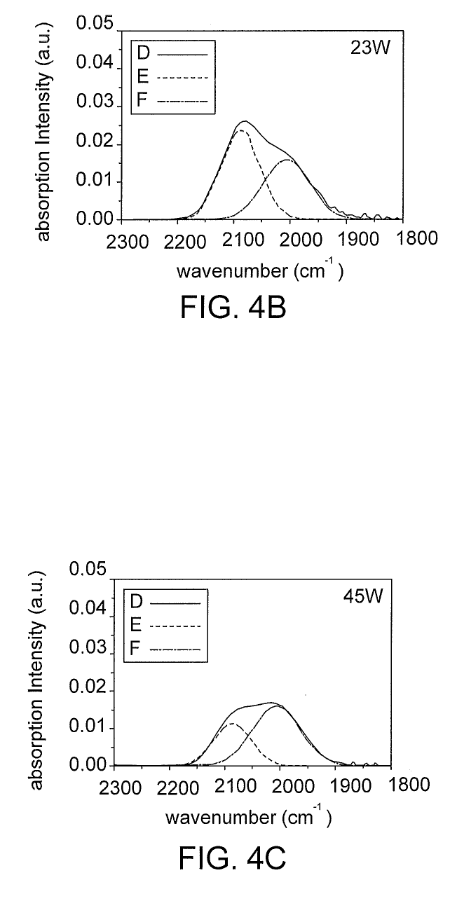

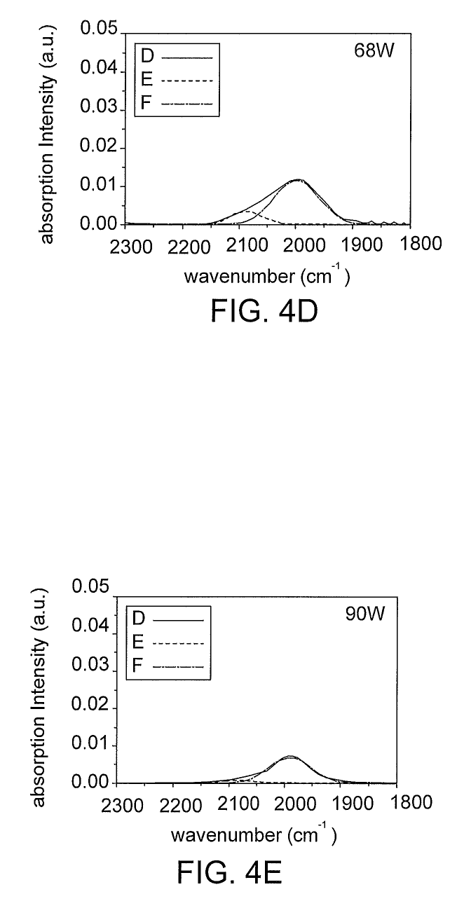

FIG. 4A, FIG. 4B, FIG. 4C, FIG. 4D and FIG. 4E respectively shows results of the silicon film formed by using carbon dioxide laser powers of 0 W, 23 W, 45 W, 68 W and 90 W measured by the Fourier transform infrared spectrophotometer. In figures, the curve D is the result obtained by deducting the substrate signal from the infrared spectral analysis. The curve E and the curve F are curves fitted from the curve D. The curve E and the curve F respectively have mode peaks at different positions of wavenumber.

In figures, the range of the absorption curve is 1900 cm⁻¹-2200 cm⁻¹, belonging to the signal of Si—H bond. The position of 2100 cm⁻¹ mainly belongs to SiH₂ bond. A low absorption intensity of the mode peak at 2100 cm⁻¹ indicates a small quantity of SiH₂ bond, indicating a low probability of defect of the silicon film structure. The position at 2000 cm⁻¹ mainly belongs to SiH bond. A high ratio of the absorption intensity of the mode peak at 2000 cm⁻¹ to the absorption intensity of the mode peak at 2100 cm⁻¹ indicates a small quantity of the defect and a nice quality of the silicon film. On the contrary, a low ratio of the absorption intensity of the mode peak at 2000 cm⁻¹ to the absorption intensity of the mode peak at 2100 cm⁻¹ indicates a huge quantity of the defect, a loose structure and a nasty quality of the silicon film.

From results shown in FIG. 4A, FIG. 4B, FIG. 4C, FIG. 4D and FIG. 4E, it is found that as the power of the carbon dioxide laser becomes higher, a ratio of the intensity of the absorption peak at 2000 cm⁻¹ (curve F) to the intensity of the absorption peak at 2100 cm⁻¹ (curve E) becomes higher. It indicates that the silicon film has a low amount of defect and high quality. Particularly, the silicon film in FIG. 4E has the best quality as the absorption intensity of the mode peak at 2100 cm⁻¹ is almost zero.

<Transmission Electron Microscope (Tem) Test>

In the result of the Raman spectral test, the Raman signal shows that the silicon film has the crystal structure. However, it is still need to further analyze if the volume of the formed crystal structure is big enough to be distinguished from the amorphous structure. The structure of the silicon film is observed by a TEM herein. Situation of the crystal structure formed by various laser powers are also discussed.

No crystal particle is observed and only an amorphous silicon film of a big area is observed in the bright field image of the silicon film formed without irradiating the silicon containing alkane gas by the laser (in other words, the laser power is 0 W). Also, no signal of the crystal silicon is found in the diffraction ring image of the silicon film formed without irradiating the silicon containing alkane gas by the laser (in other words, the laser power is 0 W), identical to the result of the bright field image.

It is observed that in the bright field image, the silicon film formed by irradiating the silicon containing alkane gas by the laser of 68 W has a microcrystal particle of an average diameter of about 2 nm. The diffraction ring image of the silicon film formed by irradiating the silicon containing alkane gas by the laser of 68 W also reveals a weak diffraction ring pattern of a lattice plane.

It is observed that in the bright field image, the silicon film formed by irradiating the silicon containing alkane gas by the laser of 90 W has a microcrystal particle of an average diameter of about 5 nm, bigger than the microcrystal particle formed by irradiating by the laser of 68 W. It is presumed the silicon crystal particle of big size is formed because much crystal particles are formed due to a high laser power and the probability of growth resulted from stacking of crystal particles is high, or, the growth rate of the silicon crystal particle is improved by increasing the laser power. The diffraction ring image of the silicon film formed by irradiating the silicon containing alkane gas by the laser of 90 W also reveals a diffraction ring pattern of strong bright intensity of a lattice plane. The signals of the inner ring to the outer ring, obtained by calculating the gap distance between the rings, respectively represent the silicon crystal planes of (111), (220) and (311).

In embodiments, the silicon film having the microcrystal structure and excellent quality can by manufactured by using the plasma-enhanced chemical vapor deposition in combination with the carbon dioxide laser at the low temperature.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a silicon film, comprising:
disposing a substrate in an environment containing a silicon containing alkane gas; and
forming a silicon film on the substrate by simultaneously irradiating the silicon containing alkane gas by a carbon dioxide laser and performing a plasma-enhanced chemical vapor deposition.

2. The method for forming the silicon film according to claim 1, wherein the silicon containing alkane gas comprises silane.

3. The method for forming the silicon film according to claim 1, wherein the silicon film has a microcrystal structure.

4. The method for forming the silicon film according to claim 1, wherein the silicon containing alkane gas comprises silane, the silicon film has a microcrystal structure.

5. The method for forming the silicon film according to claim 1, wherein a temperature of the plasma-enhanced chemical vapor deposition is 25° C.-400° C.

6. The method for forming the silicon film according to claim 1, wherein a power of the plasma-enhanced chemical vapor deposition is 10 W-1000 W, a pressure of the plasma-enhanced chemical vapor deposition is 0.1 torr-100 torr, a flow rate of the silicon containing alkane gas is 1 sccm-1500 sccm.

7. The method for forming the silicon film according to claim 1, wherein a power of the laser is 10 W-1000 W.

8. A method for forming a silicon film having a microcrystal structure, comprising:
providing a plasma-enhanced chemical vapor deposition system, wherein the plasma-enhanced chemical vapor deposition system comprises:
a reaction chamber; and
a top electrode and a bottom electrode disposed in the reaction chamber, wherein the top electrode is opposite to the bottom electrode;
disposing a substrate on the bottom electrode;
supplying a silane gas into reaction chamber; and
forming a silicon film having a microcrystal structure by simultaneously irradiating the silane gas in the reaction chamber by a carbon dioxide laser by a power of 10 W-1000 W and performing a plasma-enhanced chemical vapor deposition by a temperature of 25° C.-400° C.

9. The method for forming the silicon film having the microcrystal structure according to claim 8, wherein a power of the plasma-enhanced chemical vapor deposition is 10 W-1000 W, a pressure of the plasma-enhanced chemical vapor deposition is 0.1 torr-100 torr, a flow rate of the silane gas is 1 sccm-1500 sccm.
